(19) United States
(12) Patent Application Publication
(10) Pub. No.: US 2013/0168772 A1
(43) Pub. Date: Jul. 4, 2013

(54) SEMICONDUCTOR DEVICE FOR ELECTROSTATIC DISCHARGE PROTECTING CIRCUIT

(71) Applicant: Yung-Ju WEN, Taoyuan City (TW)

(72) Inventor: Yung-Ju WEN, Taoyuan City (TW)

(73) Assignee: UNITED MICROELECTRONICS CORPORATION, HSINCHU (TW)

(21) Appl. No.: 13/338,324

(22) Filed: Dec. 28, 2011

(51) Int. Cl. H01L 27/092

(52) U.S. Cl. 257/355; 257/E27.062

(57) ABSTRACT

A semiconductor device for an electrostatic discharge (ESD) protecting circuit connected to a pad is provided. The semiconductor device includes a semiconductor substrate of a first conductivity type; a plurality of metal oxide semiconductor transistors (MOSFETs) formed in the semiconductor substrate, and an isolation structure of a second conductivity type formed in the semiconductor substrate. The MOFETS are arranged in parallel. Drain electrodes of the MOSFETs are electrically connected to the pad, gate electrodes and source electrodes of the MOSFETs are connected to a constant voltage, and the gate electrodes extend in a first direction. The isolation structure includes a bottom and at least two side walls, wherein the bottom is located under the MOSFETs and the two side walls are located at two sides of the MOSFETs, and the side walls extend in the first direction.

### TECHNICAL FIELD

The present invention relates generally to a semiconductor device, and more particularly to a semiconductor device for an electrostatic discharge (ESD) protecting circuit.

### BACKGROUND

Electrostatic discharge (ESD) protecting circuits are usually used to protect integrated circuits from being damaged. Generally, ESD protecting circuits provide discharging paths required by the ESD process thereby preventing the damage to circuit devices in integrated circuits caused by the huge current during the ESD process.

Mostly, the source of electrostatic is exterior charged body. In addition, inputting pads of integrated circuits are usually connected to gate electrodes of metal oxide semiconductor transistors (MOS), and gate oxide layers are easily damaged by the huge current during electrostatic discharge. Therefore, ESD protecting circuits are required to form around inputting pads to protect them. Moreover, ESD protecting circuits can also be formed near connecting pads of power source. In summary, ESD protecting circuits are usually located aside connecting pads.

FIG. 1A is a schematic view illustrating an ESD protecting circuit which includes a pad 10 and an NMOS 11 connected to the pad 10. FIG. 1B is a schematic cross sectional view of FIG. 1A. As shown in FIG. 1B, a gate electrode 110 and a source electrode 111 of the MOS 11 are grounded, and a drain electrode 112 is electrically connected to the pad 10. FIG. 1C illustrates a current-voltage characteristics diagram of the NMOS 11.

Referring to FIGS. 1A, 1B, 1C together, a gate voltage Vg is 0. An external power source 19 is used to simulate the ESD process. The power source 19 produces a testing pulse having a rise time of 10 nano-seconds (ns) and a width of 100 ns. As indicated by the dashed arrow in FIG. 1A, the testing pulse runs through the pad 10 and enters into the drain electrode 112 of the NMOS 11. If the voltage of the testing pulse isn't reach to the trigger voltage Vₜ₁, a drain current I_{c} from the drain electrode 112 to the source electrode 111 is very small. If the voltage of the testing pulse touches the trigger voltage Vₜ₁, a NPN bipolar junction transistor (BJT) 12, which includes the drain electrode 112, the source electrode 111, and a P type substrate 119, is switched on. As a result, the current amplifying effect (which is represented by a formula I_{c}=β*I_{sub}, wherein I_{sub} represents the on-current) of the NPNBJT 12 causes that I_{c} surges to Iₜ₁. Accordingly, a voltage drop V_{ds} between the drain electrode 112 and the source electrode 111 drops to V_{hold}. Basically, this is the operation principle of ESD protecting circuits.

A point (Vₜ₂, Iₜ₂) in FIG. 1C indicates a maximum withstand current It2 of the NMOS 11 and the corresponding voltage drop V_{ds}. If an ESD current ID to the drain electrode 112 is greater than Iₜ₂, the circuit would have an unrecoverable damage. Thus, there is a desire to provide a technique which is capable of improving the maximum withstand current Iₜ₂ of the NMOS 11 thereby improving the lifetime of ESD protecting circuits.

### SUMMARY

In one embodiment, a semiconductor device for an electrostatic discharge (ESD) protecting circuit connected to a pad is provided. The semiconductor device includes a semiconductor substrate of a first conductivity type; a plurality of metal oxide semiconductor transistors (MOSFETs) formed in the semiconductor substrate, and an isolation structure of a second conductivity type formed in the semiconductor substrate. The MOFETS are arranged in parallel. Drain electrodes of the MOSFETs are electrically connected to the pad, gate electrodes and source electrodes of the MOSFETs are connected to a constant voltage, and the gate electrodes extend in a first direction. The isolation structure includes a bottom and at least two side walls, wherein the bottom is located under the MOSFETs and the two side walls are located at two sides of the MOSFETs, and the side walls extend in the first direction.

In this semiconductor device, a portion of discharge paths are cut off by the isolation structure. As a result, the base resistances between the different MOSFETs and a guard ring are the same. Accordingly, the current load can be evenly distributed to all the discharge paths, and thus the maximum withstand current and the lifetime of ESD protecting circuits can be improved.

### BRIEF DESCRIPTION OF THE DRAWINGS

The present invention will become more readily apparent to those ordinarily skilled in the art after reviewing the following detailed description and accompanying drawings, in which:

FIG. 1A is a schematic view illustrating an ESD protecting circuit which includes a pad and an NMOS connected to the pad;

FIG. 1B is a schematic cross sectional view of FIG. 1A;

FIG. 1C is a current-voltage characteristics diagram of the NMOS shown in FIG. 1A.

FIG. 2A is a schematic top view of a MOSFET in an ESD protecting circuit in according with a first embodiment;

FIG. 2B is a schematic cross sectional view taken along a line A-A′ in FIG. 2A;

FIG. 3A is a schematic top view of a MOSFET in an ESD protecting circuit in according with a second embodiment;

FIG. 3B is a schematic cross sectional view taken along a line B-B′ in FIG. 3A;

FIG. 3C is a schematic cross sectional view of a MOSFET in an ESD protecting circuit in according with a third embodiment

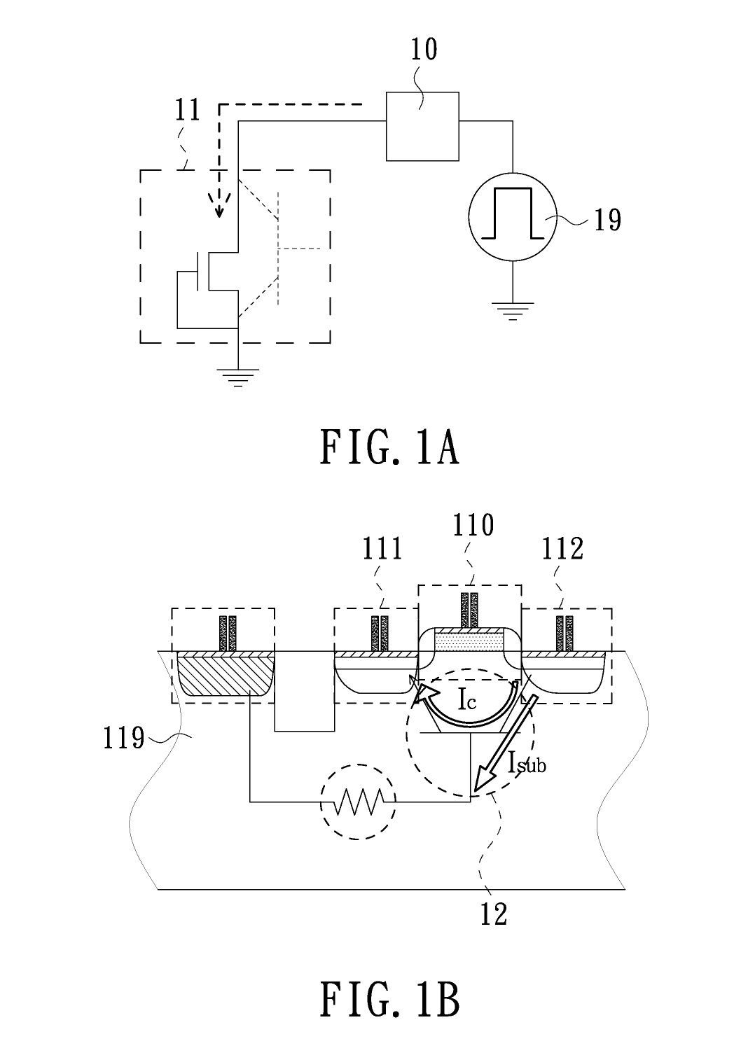

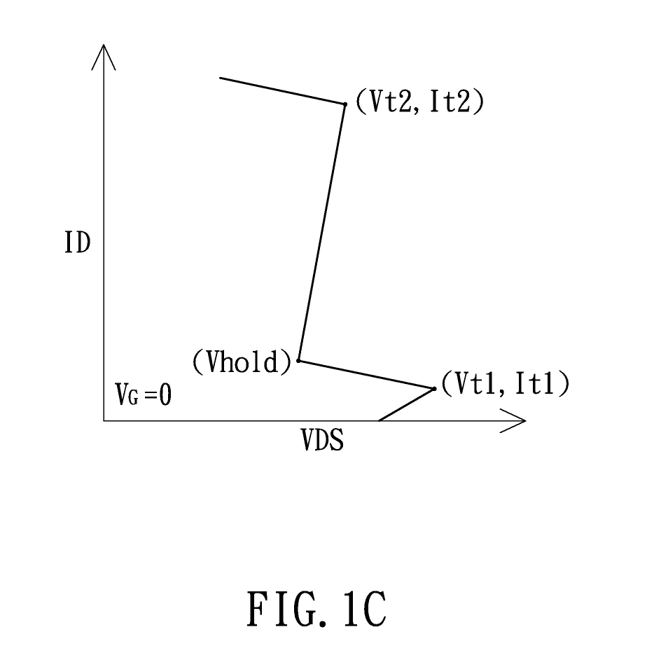

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

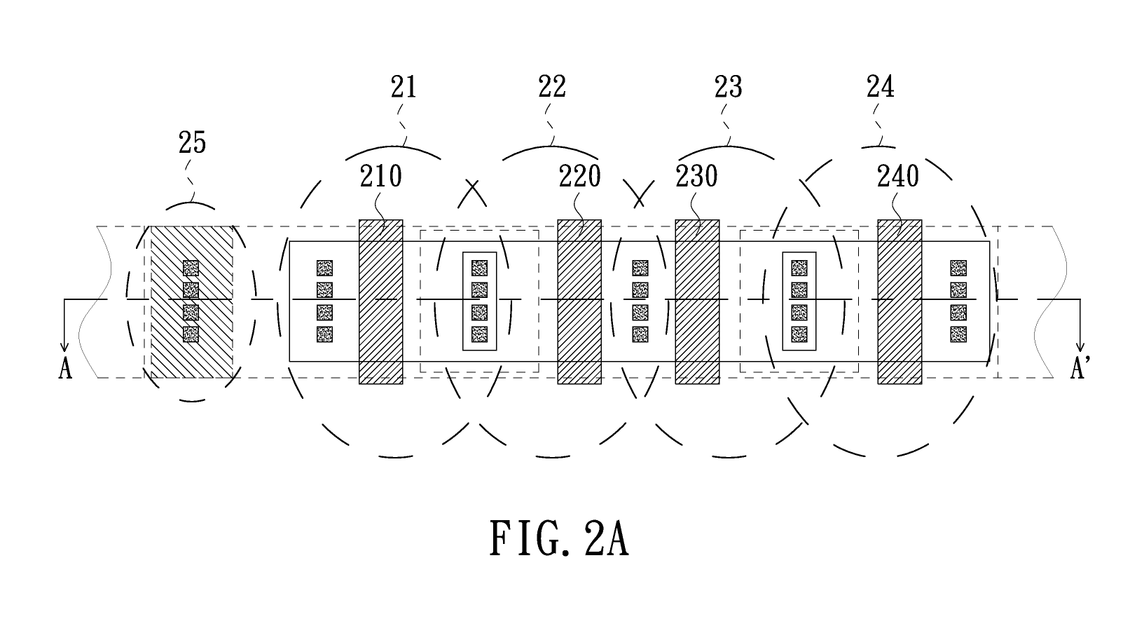

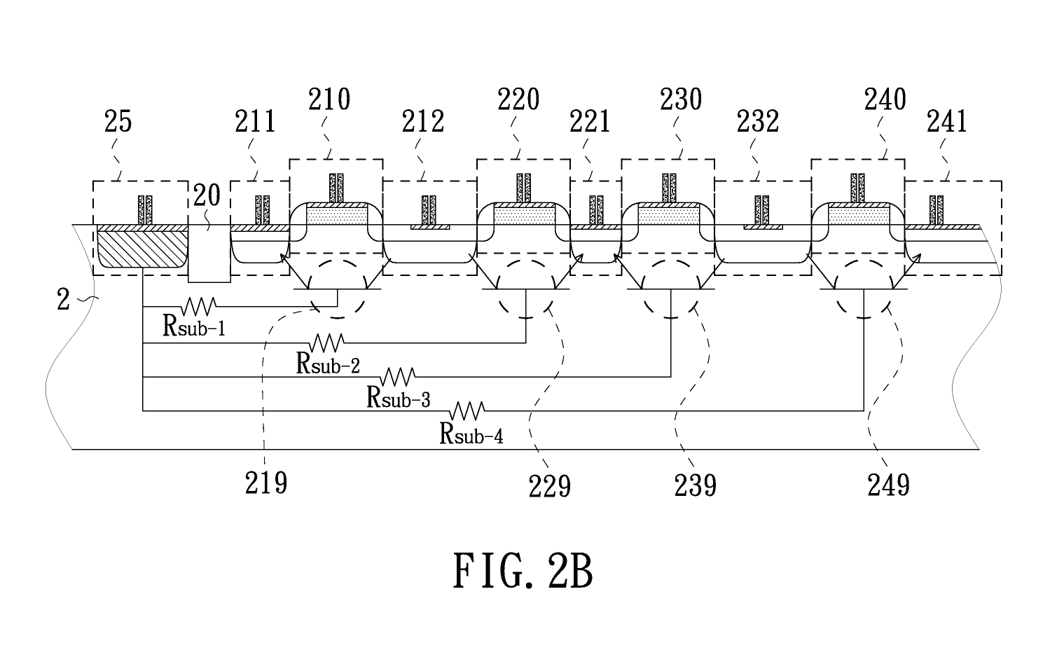

To improve the maximum withstand current of NMOS, the present embodiment provides a metal oxide semiconductor field effect transistor (MOSFET) having a multi-finger configuration. FIG. 2A is a schematic top view of a MOSFET in an ESD protecting circuit in according with a first embodiment, and FIG. 2B is a schematic cross sectional view taken along a line A-A′ in FIG. 2A. It is to be noted that FIGS. 2A and 2B mainly illustrates a left part of the MOSFET. The MOSFET includes a P type silicon substrate 2 which defines four n-type MOSFETs 21, 22, 23, and 24. The n-type MOSFETs 21, 22, 23 and 24 are separated from a guard ring 25 by a shallow trench isolation (STI) structure 20. Gate electrodes 210, 220, 230, 240 of the n-type MOSFETS 21, 22, 23, 24 are arranged in parallel to form a multi-finger like pattern. Sources electrodes 211, 221, 241 and drain electrodes 212, 232 are formed at two opposite sides of the gate electrodes 210, 220, 230, 240, respectively. The n-type MOSFETS 21, 22, 23, 24 are connected in a parallel manner, which means that the gate electrodes, 210, 220, 230, 240, source electrodes 211, 221, 241, the guard ring 25 are all connected to a constant voltage, and the drain electrodes 212, 232 are electrically connected to a connecting pad. In the present embodiment, the constant voltage is zero. That is, the gate electrodes, 210, 220, 230, 240, source electrodes 211, 221, 241, and the guard ring 25 are grounded. Besides, the gate electrodes 210, 220, 230 and 240 extend in a first direction, in other words, the lengthwise direction of the gate electrodes 210, 220, 230 and 240 is the first direction. As such, discharge paths can be combined with adequate area and thus the maximum withstand current of the NMOS is improved.

As shown in FIG. 2B, the base resistances formed between n-type MOSFETS 21, 22, 23, 24 and the guard ring 25 are marked as R_{sub-1}, R_{sub-2}, R_{sub-3}, and R_{sub-4}, respectively. Since distances between the guard ring 25 and the different n-type MOSFETS 21, 22, 23, 24 are also different; thus R_{sub-1}, R_{sub-2}, R_{sub-3}, and R_{sub-4} are also different (R_{sub-4}>R_{sub-3}>R_{sub-2}>R_{sub-1}). In this way, if the current is the same, the voltage corresponding to R_{sub-4} is the maximum one. That is to say, an NPNBJT 249 in the n-type MOSFET 24 that is located at a position near a center of a chip would be switched on prior to NPNBJTs 219, 229, 239 in other n-type MOSFETS 21, 22, 23, respectively. As described above, the voltage drop V_{ds} of the n-type MOSFET 24 would drop from Vₜ₁ to V_{hold} after switched on. In addition, V_{hold} is far less than Vₜ₁. As a result, the NPNBJTs 219, 229, 239 in other n-type MOSFETS 21, 22, 23 can hardly be switched on. Therefore, all the electrode discharge current would only run through the NMOSFET 24 in the center and the other discharge paths are not efficiently used.

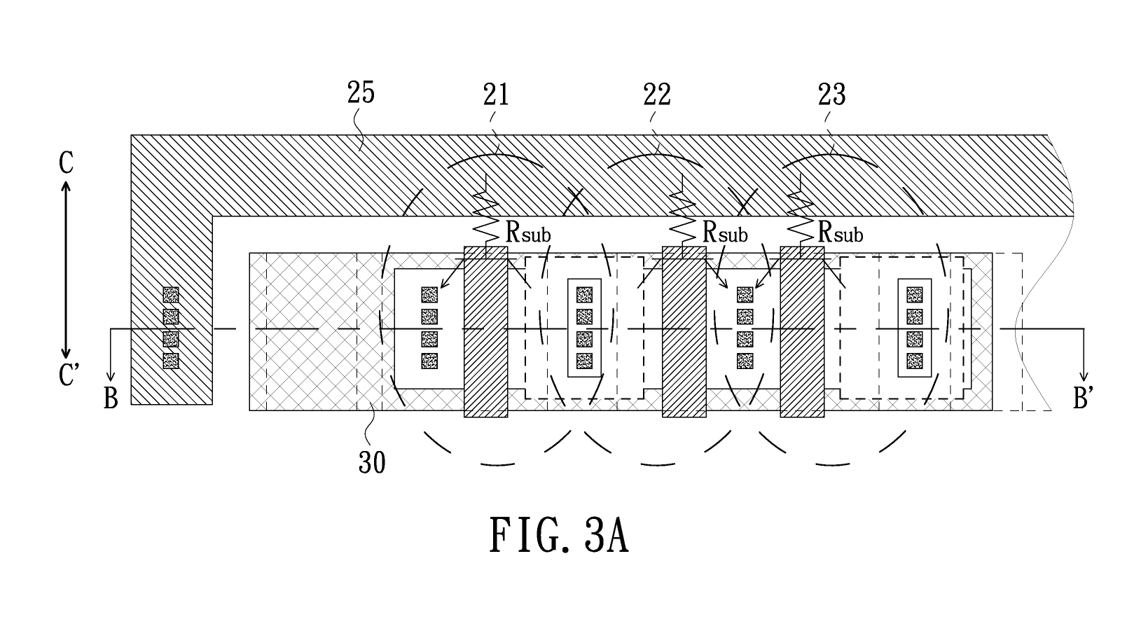

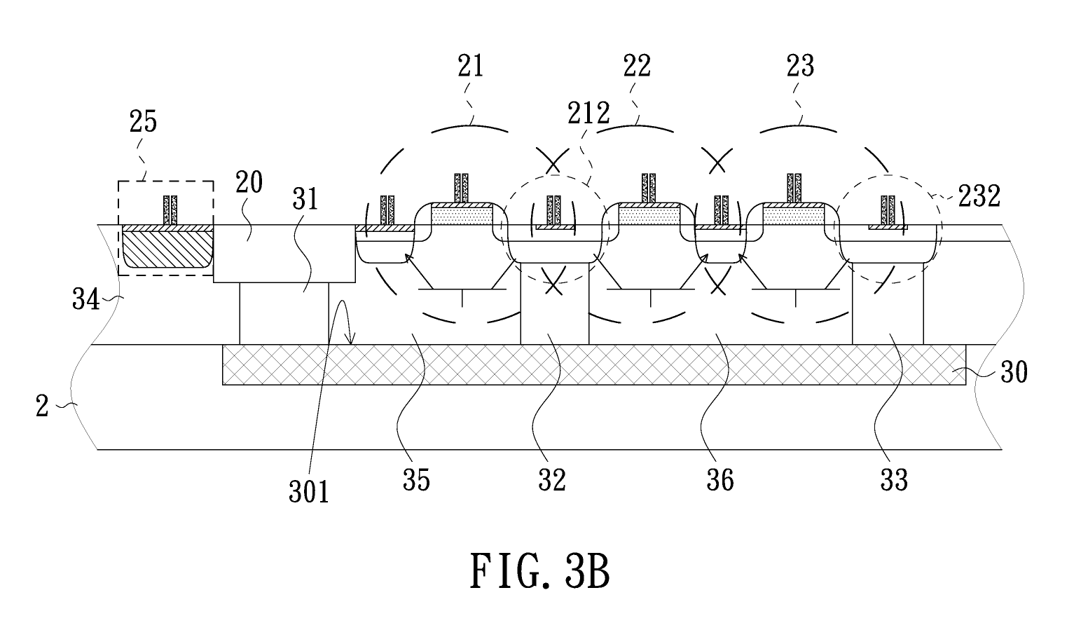

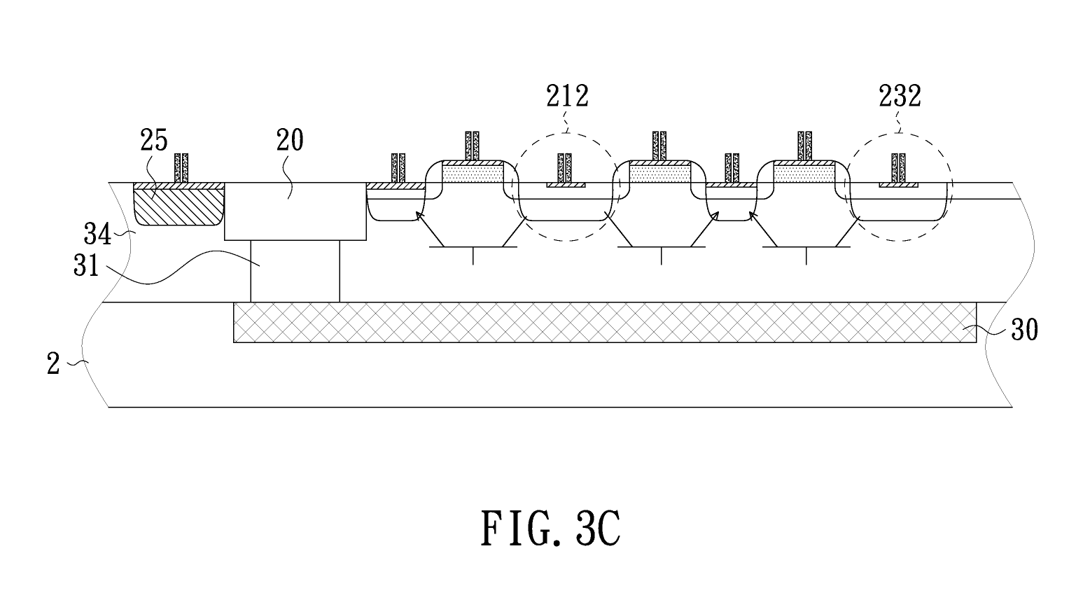

To further overcome the above problem, a second embodiment of the present invention provides another MOSFET for an ESD protecting circuit. FIG. 3A is a schematic top view of the MOSFET and FIG. 3B is a schematic cross sectional view taken along a line B-B′ in FIG. 3A. To fully utilize the discharge paths provided by all the MOSFETS, the present embodiment avoid producing different resistances between the guard ring 25 and different NPNBJTs. A deep N-well 30 is formed in the P-type silicon substrate 2 beneath the MOSFETs 21, 22 and 23. In addition, N wells 31, 32, 33 can be used to isolate adjacent n-type MOSFETS. In the present embodiment, N wells 31, 32, 33 are formed beneath the STI structure 20, the drain electrode 212, and the drain electrode 232, respectively. Besides, N-wells 34, 35 and 36 are formed next to each other at a side of the N-wells 31, 32 and 33.

As such, two opposite lateral sides and the bottom of P type channels of all the n-type MOSFETS are surrounded by an N type isolation structure (including the deep N well 30, and the N wells 31, 32, 33). As a consequence, the original discharge paths between the n-type MOSFETS 21, 22 and 23 at different positions and the two sides of the guard ring 25 are cut off. However, the guard ring 25 surrounds and encloses the multi-finger like MOSFET structure. Therefore, base resistance R_{sub} can also be defined between a top and a bottom of the guard ring 25. However, on this condition, each of the n-type MOSEFETs has a same distance to the top and the bottom of the guard ring 25. Thus, R_{sub} of different n-type MOSFETs are the same. As a result, if the current flux is the same, the NPNBJTs in the n-type MOSFETS 21, 22 and 23 would be switched on simultaneously. Therefore, more discharge paths can be used and thus the maximum withstand current is improved.

Besides, the deep N-well 30, and the N-wells 31, 32, 33 are formed with dopants same to that in the original process. That is to say, there is no need to use additional photo masks. The deep N well 30 and the N wells 31, 32, 33 cooperatively defines an N-type isolation structure, wherein the deep N-well 30 is a bottom of the N-type isolation structure and the N-wells 31, 32, 33 are side walls of the N-type isolation structure. The bottom, in other words, the deep N well 30, is located under the MOSFETS, and the side walls, which are defined by the N wells 31, 32 and 33, are parallel to each other and are formed directly on an upper surface 301 of the deep N-well 30. At least one MOSFET is formed between any two adjacent side walls. In other words, the side walls (or the N wells 31, 32 and 33) are formed at lateral sides of the MOSFETS. The lateral sides of each MOSFET are the sides directly facing toward or opposite to adjacent MOSFETS. For example, the MOSFET 21 is formed between the N wells 31 and 32, and the MOSFETS 22, 23 are formed between the N wells 32 and 33. In addition, the side walls also extend in the first direction (as indicated by an arrow CC′ in FIG. 3A). The width of the N-wells 31, 32 and 33 can be coinciding with the design rule of semiconductor devices. That is, the N-wells 31, 32 and 33 are still capable of providing isolation function when the width thereof is less than or equal to that of the STI structure 20, the drain electrodes 212, 232. Therefore, the N-wells 31, 32, 33 don't increased the device area required.

Moreover, the deep N well 30 and the N well 31 formed at two sides of the STI structure 20 are the most important N type isolations. Therefore, if the number of the N-wells (i.e., the N wells 32, 33 in FIG. 3B) under each of the drain electrode is reduced or the N-wells are even omitted, the deep N well 30 still reduces the difference of the base resistances R_{sub}. Specifically, the N well 31, which extends in the first direction, still cuts off the paths for forming base resistance between inner elements and opposite sides of the outer guard ring 25, there is only one path, between a top outer portion of the guard ring 25 (FIG. 3A) and a bottom outer portion of the guard ring 25 (not shown in FIG. 3A), form the base resistance R_{sub}. Therefore, a MOSFET for a ESD protecting circuit in accordance with another embodiment, as shown in FIG. 3C, are still capable of reducing the difference of the base resistances R_{sub} when the number of the N wells is reduced or even the N wells are omitted.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A semiconductor device, being used in an electrostatic discharge (ESD) protecting circuit connected to a pad, the semiconductor device comprises:
a semiconductor substrate of a first conductivity type;
a plurality of metal oxide semiconductor transistors (MOSFETs), formed in the semiconductor substrate and arranged in parallel, drain electrodes of the MOSFETs being electrically connected to the pad, gate electrodes and source electrodes of the MOSFETs being connected to a constant voltage, and the gate electrodes extending in a first direction; and
an isolation structure of a second conductivity type, formed in the semiconductor substrate and comprising a bottom and at least two side walls, wherein the bottom is located under the MOSFETs and the at least two side walls are located at two sides of the MOSFETs, and the side walls extend in the first direction.

2. The semiconductor device of claim 1, wherein the semiconductor substrate is a P-type silicon substrate, the MOSFETS are N-type MOSFETS, the isolation structure is of a N-type, the gate electrodes and source electrodes of the MOSFETS are grounded, and the isolation structure comprises a deep N well and a plurality of N-wells formed at the side walls.

3. The semiconductor device of claim 1, further comprising:
a shallow trench isolation structure, formed in the semiconductor substrate and surrounding peripheral portions of the MOSFETs, and
a guard ring, formed in the semiconductor substrate and surrounding the shallow trench isolation structure.

4. The semiconductor device of claim 3, wherein the side walls are formed under the shallow trench isolation structure.

5. The semiconductor device of claim 4, wherein the width of the side walls is less than or equal to that of the shallow trench isolation structure.

6. The semiconductor device of claim 1, wherein the isolation structure further comprises an isolation wall, formed in the semiconductor substrate and located under the drain electrodes of the MOSFETS, and the isolation wall extends in the first direction.

7. The semiconductor device of claim 6, wherein a width of the isolation wall is less than or equal to that of the drain electrodes.

8. The semiconductor device of claim 1, wherein the sidewalls of the isolation structure are located at lateral sides of the MOSFETS that facing toward or opposite to adjacent MOSFETS.
